(19) United States
(12) Patent Application Publication
(10) Pub. No.: US 2018/0122731 A1
(43) Pub. Date: May 3, 2018

(54) PLATED DITCH PRE-MOLD LEAD FRAME, SEMICONDUCTOR PACKAGE, AND METHOD OF MAKING SAME

(71) Applicant: Texas Instruments Incorporated, Dallas, TX (US)

(72) Inventors: Daiki Komatsu, Beppu (JP); Takafumi Ando, Beppu (JP)

(73) Assignee: Texas Instruments Incorporated, Dallas, TX (US)

(21) Appl. No.: 15/488,594

(22) Filed: Apr. 17, 2017

Related U.S. Application Data
(60) Provisional application No. 62/416,605, filed on Nov. 2, 2016.

(51) Int. Cl. H01L 23/498; H01L 21/78; H01L 21/48; H01L 23/495; H01L 23/00

(52) U.S. Cl. CPC H01L 23/49805; H01L 21/78; H01L 21/4828; H01L 2224/48247; H01L 23/49558; H01L 24/48; H01L 23/49582

(57) ABSTRACT

An integrated circuit chip package and method for making the same, wherein the integrated circuit chip package includes conductive leads. The method includes trenching a plurality of conductive lead structures along a parting line, plating the trenches with a plating layer, and singulating the lead frame assembly along the parting line to produce an integrated circuit chip package with conductive leads having unplated side portions and plated recessed portions.

### REFERENCE TO RELATED APPLICATION

Under 35 U.S.C. §119, this application claims priority to, and the benefit of, U.S. Provisional Patent Application No. 62/416,605, entitled “Plated Ditch Pre-Mold Lead Frame for Wettable Flank QFN”, filed on Nov. 2, 2016, the entirety of which is hereby incorporated by reference.

### BACKGROUND

Integrated circuit devices generally include an integrated circuit (IC) chip and a lead frame which are sealed within a protective enclosure. Such IC chip packages, as they are often called, find wide use in consumer electronics, computers, automobiles, telecommunications, military applications, etc. The lead frame electrically couples the IC chip to circuitry (e.g., printed circuit board) external to the package. The lead frame is typically formed from a highly electrically and thermally conductive material, such as copper or copper alloys. The lead frame material is typically stamped or etched into a plurality of leads, and a central area, called a die attach pad, onto which the IC chip is attached. The IC chip is electrically connected to the leads, usually by wire bonding, and the device is encapsulated by a molded structure. Then, the IC chip package is mounted to another component, such as a circuit board, and electrically coupled thereto.

One type of IC chip package-is a quad flat no-lead package. This surface mount chip package includes one or more IC dies encapsulated in mold resin, and a plurality of perimeter leads on the bottom and/or sides thereof for connecting the one or more IC dies to contacts on an associated circuit board or other component.

### SUMMARY

Disclosed examples include an integrated circuit chip package and method for making the same, wherein the package includes plated conductive leads. In one example, a method for making an integrated circuit chip package comprises providing a premolded lead frame assembly having opposing first and second sides, the premolded lead frame assembly including an array of lead frames at least partially surrounded by a first molded structure, each lead frame including a die attach pad and a plurality of conductive lead structures spaced apart from the die attach pad, the first molded structure interposed at least between adjacent conductive lead structures along a parting line, forming a trench (ditch) in at least one of the plurality of conductive lead structures along the parting line, the trench opening to the second side of the premolded lead frame assembly, plating at least the trench, coupling an integrated circuit die to the die attach pad on the first side of the premolded lead frame assembly, wirebonding the integrated circuit die to the plurality of conductive lead structures on the first side of the premolded lead frame assembly, forming a second molded structure over the die and plurality of conductive lead structures, and singulating the integrated circuit chip package, the singulating including severing the first molded structure, the second molded structure and the plurality of conductive lead structures along the parting line resulting in an integrated circuit chip package having at least one conductive lead with a side portion and a plated recessed portion.

### BRIEF DESCRIPTION OF THE DRAWINGS

FIG. 1 is a perspective view of an example IC chip package according to one embodiment;

FIG. 2 is an enlarged portion of FIG. 1 showing further details of conductive leads of the IC chip package;

FIG. 3 is a flowchart illustrating an example method of making the IC chip package of FIGS. 1 and 2;

FIG. 4 is a plan view of an example premolded lead frame assembly including an array of lead frames and a first molded structure;

FIG. 5 is a cross-sectional view of the premolded lead frame assembly taken through the line 5-5 in FIG. 4;

FIG. 6 is a cross-sectional view of the premolded lead frame assembly of FIG. 5 after applying and patterning an etch mask layer;

FIG. 7 is a cross-sectional view of the premolded lead frame assembly after forming a trench in the conductive lead structure;

FIG. 8 is a cross-sectional view of the premolded lead frame assembly after plating of the die attach pad and conductive lead structure;

FIG. 9 is a cross-sectional view of the premolded lead frame assembly after die attachment, wirebonding and forming a second molded structure; and,

FIG. 10 illustrates singulation of the IC chip package.

### DETAILED DESCRIPTION

In the drawings, like reference numerals refer to like elements throughout, and the various features are not necessarily drawn to scale. In the following discussion and in the claims, the terms “including”, “includes”, “having”, “has”, “with”, or variants thereof are intended to be inclusive in a manner similar to the term “comprising”, and thus should be interpreted to mean “including, but not limited to . . . ” Also, the term “couple” or “couples” is intended to include indirect or direct electrical or mechanical connection or combinations thereof. For example, if a first device couples to or is coupled with a second device, that connection may be through a direct electrical connection, or through an indirect electrical connection via one or more intervening devices and connections.

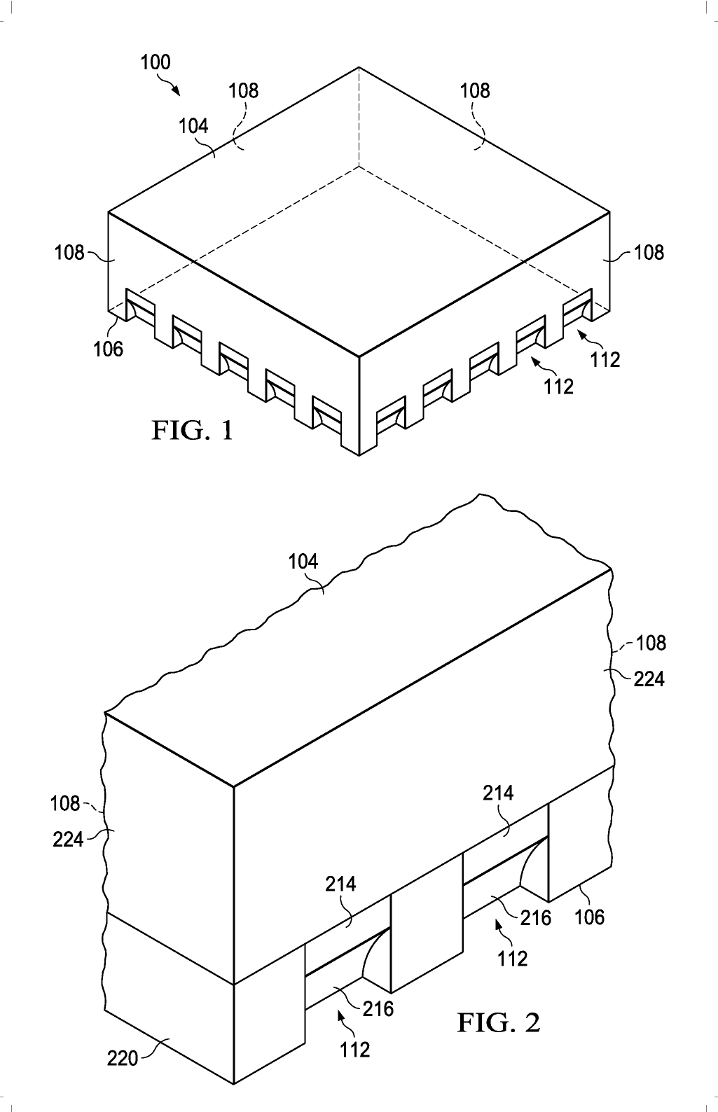

Referring initially to FIG. 1, an example IC chip package 100 is illustrated. The IC chip package 100 is a quad-flat no leads (QFN) package having a generally rectangular or square shape with a top surface 104, a bottom surface 106 and four side surfaces 108 extending between the top surface 104 and bottom surface 106. Spaced about the periphery of the IC chip package 100 are a plurality of conductive leads 112 for attaching the IC chip package 100 to other components. As will be appreciated, the IC chip package 100 contains one or more IC dies (not shown in FIG. 1) coupled to the plurality of conductive leads 112.

With reference to FIG. 2, each conductive lead 112 has at least a side portion 214 thereof exposed to one of the side surfaces 108 of the IC chip package 100. In addition, each conductive lead 112 has a plated recess or recessed portion 216 extending from the side portion 214 to the bottom surface 106 of the chip package 100. In accordance with the present disclosure, the plated recessed portion 216 of each conductive lead 112 is plated to enhance solder wettability during subsequent processing steps when the IC chip package 100 is coupled to, for example, a printed circuit board or other component. As will become apparent, side portion 214 of each conductive lead 112 is typically unplated, although in some applications it can be plated if desired.

As best seen in FIG. 2, the IC chip package 100 further includes a first molded structure 220 adjacent/between the conductive leads 112, and a second molded structure 224 formed above the first molded structure 220. As will also become apparent in connection with the remaining figures and description, the first molded structure 220 is formed in a separate process from the second molded structure.

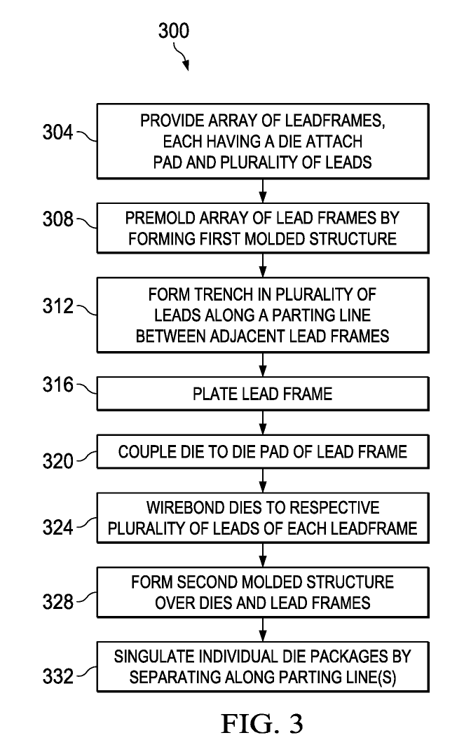

Turning now to FIG. 3, an example method of making the IC chip package 100 is illustrated in flow chart format and identified generally by reference numeral 300. The method begins with process step 304 where an array of lead frames is provided. The lead frames each include a die attach pad and a plurality of unplated conductive lead structures surrounding the die attach pad.

In process step 308, the array of lead frames is premolded by forming a first molded structure. The first molded structure generally occupies the interstitial regions between the die pads, conductive lead structures and/or any other components of the lead frames.

In process step 312, a trench is formed in the plurality of conductive lead structures of each lead frame along a parting line between adjacent lead frames. As will be described in more detail, the trench can be formed in any suitable manner, including by laser cutting, sawing or an etching process as disclosed herein.

After forming the trench, the conductive lead structures and/or die pads etc. are plated with a suitable material, such as tin etc. in process step 316.

Once plated, IC dies are then mounted (coupled) to the die attach pads in process step 320 and then wirebonded to the conductive lead structures in process step 324. A second molded structure is then formed over the IC dies and lead frames in process step 328.

In process step 332, individual IC chip packages are singulated by separating the same along parting lines to result in the structure shown in FIGS. 1 and 2.

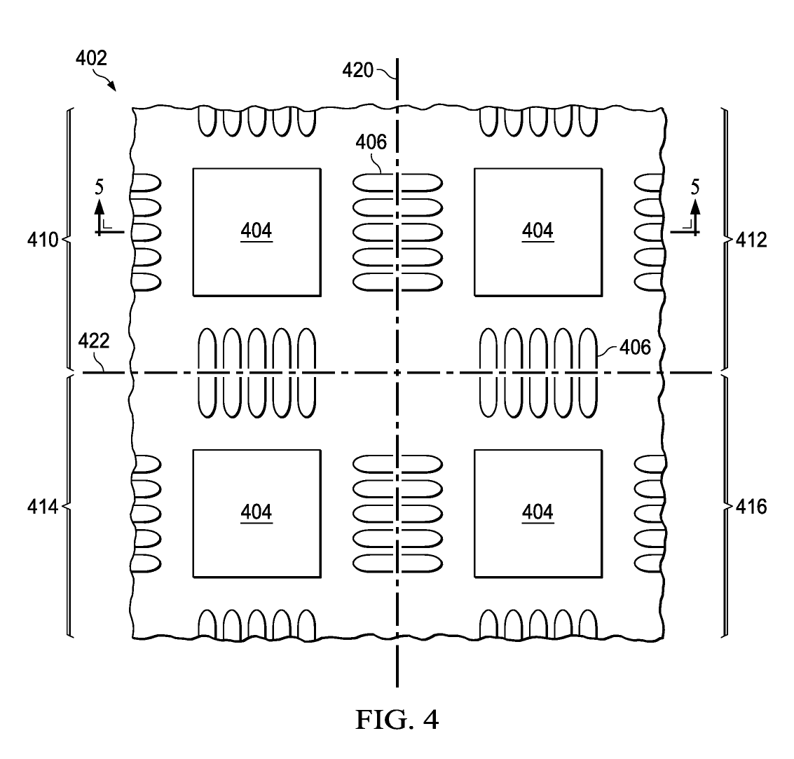

The method 300 will now be described in connection with remaining FIGS. 4-10. Beginning with FIG. 4, a portion of an exemplary premolded lead frame assembly 402 is illustrated. The premolded lead frame assembly 402 includes an array of lead frames each having a die attach pad 404 and a plurality of conductive lead structures 406 arranged about the die attach pad 404. It should be appreciated that only four premolded lead frames 410, 412, 414 and 416 are illustrated, but that the premolded lead frame assembly 402 can include any number of lead frames. Further, conductive lead structures 406 between adjacent lead frames are initially joined together and arranged along parting lines 420 and 422. For the purposes of this disclosure, the conductive lead structures 406 become respective conductive leads 112 of respective IC chip packages after singulation, as will be described in more detail below.

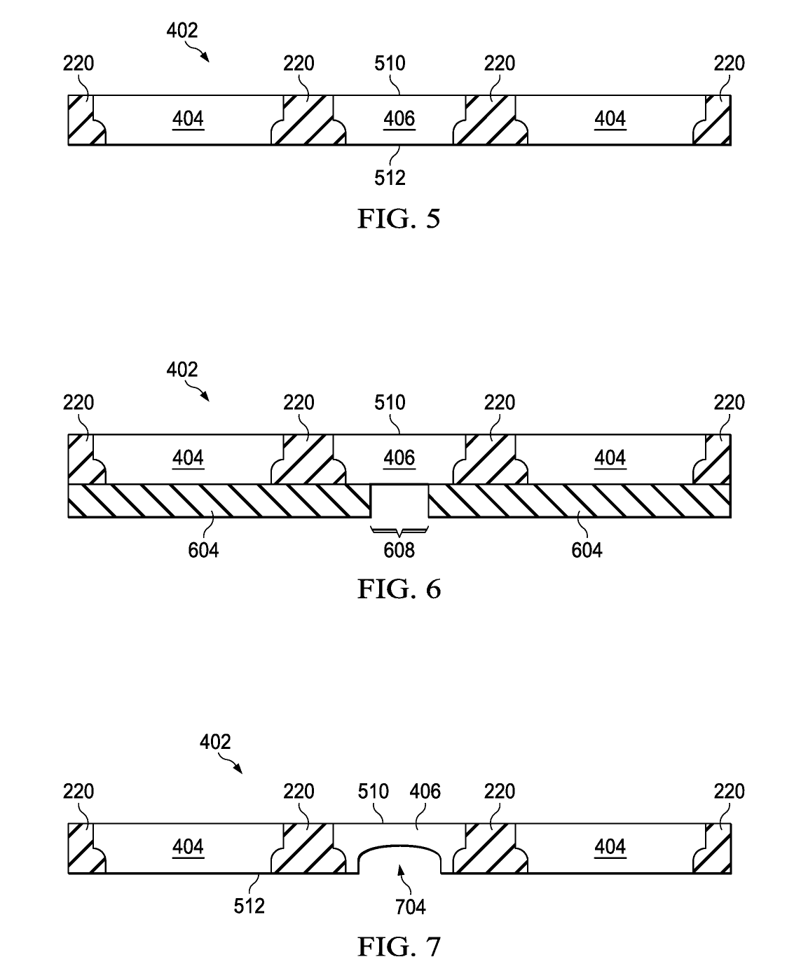

As noted above, the premolded lead frame assembly 402 includes first molded structure 220. As shown in FIG. 5, which is a cross-sectional view of the premolded lead frame assembly 402 taken along the line 5-5 in FIG. 4, the first molded structure 220 occupies regions between the die attach pads (DAPA) 404 and conductive lead structure 406. In general, the first molded structure 220 is flush with the die attach pads 404 and conductive lead structure 406 such that the premolded lead frame assembly 402 has a generally planar top (first) side 510 and bottom (second) side 512. As will be appreciated, the premolded lead frame 402 can be made in any suitable process, such as by providing the array of lead frames in method step 304 and forming the first molded structure 220 as set forth in process step 308.

With reference to FIGS. 6 and 7, a photoresist or other etch mask layer 604 is applied to the bottom side 512 of the premolded lead frame assembly 402. The etch mask layer 604 is then patterned to expose the conductive lead structure 406 in a region to be trenched, identified by reference numeral 608. An etching process is then performed to remove material from the conductive lead structure 406 thereby creating a trench 704 (see process step 312). The trench 704 in the example embodiment extends entirely across the width (e.g., direction normal to page in FIGS. 6 and 7) of the conductive lead structure 406 along a respective parting line 422 or 424. In other examples, the trench 704 may not extend entirely across the width of the conductive lead structure 406. Further, the trench 704 has a concave profile, but other profiles are possible. As will be appreciated, other approaches in addition to etching can be used to form the trench 704. The etch mask layer 604 is removed after formation of the trench 704.

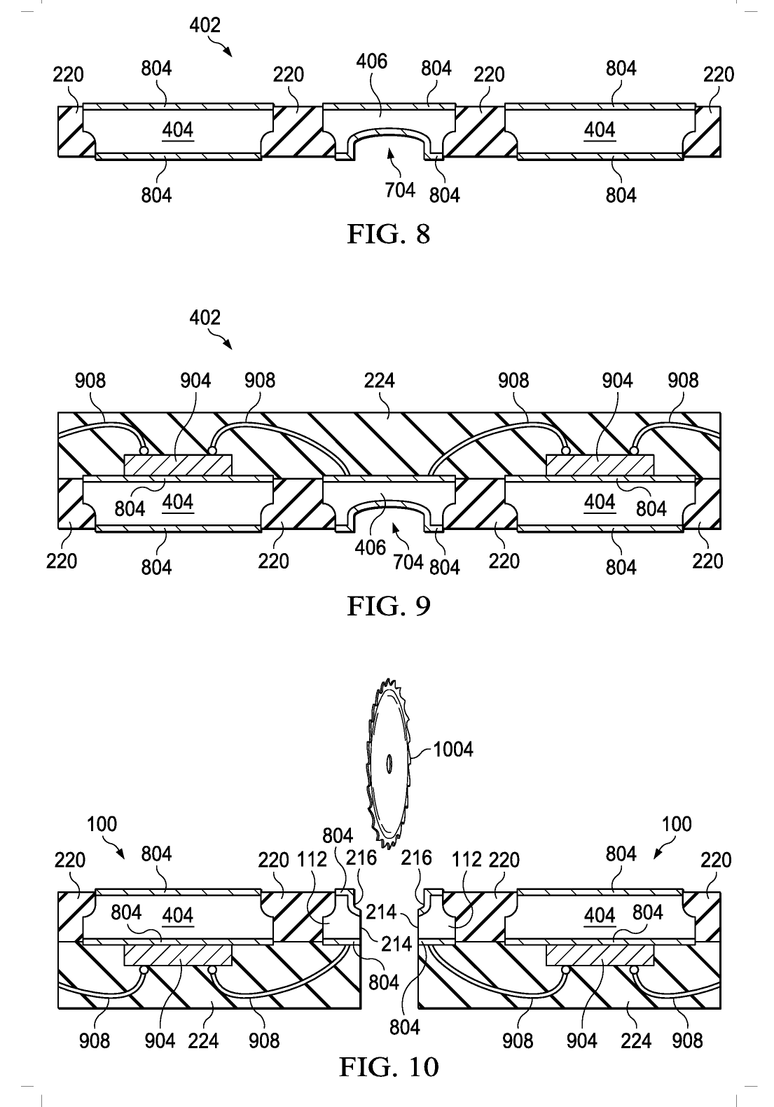

In FIG. 8, after trench formation, the conductive portions of the premolded lead frame 402, including the die attach pads 404 and conductive lead structures 406, undergo a plating process (see process step 316). The plating process deposits a plating layer 804, such as tin, or other metal plating that enhances solder wettability during subsequent processing steps.

In FIG. 9, IC dies 904 are mounted (coupled) to the plated die attach pads 404 (see process step 320) and electrically coupled to conductive lead structures 406 via wirebonds 908 (see process step 324). Then, second molded structure 224 is formed over the dies 904, plated die attach pads 404, wirebonds 908 and conductive lead structures 406, as outlined process step 328.

Finally in FIG. 10, individual IC chip packages 100 are singulated using saw 1004 (or other separating device) along parting lines 420 and 422. As parting lines 420 and 422 extend across the conductive lead structures 406, separating the IC chip packages 100 along these parting lines 420 and 422 exposes the unplated side portion 214 of each conductive lead 112. The remaining portion of the trench 704 and plating layer 804 thereon corresponds to the plated recessed portion 216. It should now be understood that the profile of the trench 704 produces the contour or shape of the plated recessed portion 216 of each conductive lead 112.

As compared to other methods of forming a recessed, wettable conductive lead, the present disclosure utilizes only a single plating step after trench formation. In addition, as compared to approaches that do not utilize a premolded lead frame, the first molded structure 220 of the present disclosure acts to block molding material leakage around the conductive lead structures during encapsulation of the IC die with the second molded structure 224. That is, unlike other approaches, the second molded structure 224 is blocked from flowing into the trenched region of the conductive lead structures 406 by the first molded structure 220. This feature facilitates full width trenches that produce conductive leads 112 with full width recessed portions 216 that are less likely to capture burrs and other debris during singulation as compared to partial width trenching (slotted leads) techniques that result in recessed regions of reduced size.

The above examples are merely illustrative of several possible embodiments of various aspects of the present disclosure, wherein equivalent alterations and/or modifications will occur to others skilled in the art upon reading and understanding this specification and the annexed drawings. Modifications are possible in the described embodiments, and other embodiments are possible, within the scope of the claims.

1. A method for making an integrated circuit chip package, comprising:
providing a premolded lead frame assembly, including:
opposing first and second sides, and
an array of lead frames at least partially surrounded by a first molded structure, each lead frame including a die attach pad and a plurality of conductive lead structures spaced apart from the die attach pad, the first molded structure interposed at least between adjacent conductive lead structures along a parting line;
forming a trench in at least one of the plurality of conductive lead structures along the parting line, the trench opening to the second side of the premolded lead frame assembly;
depositing a plating layer over at least the trench;
coupling an integrated circuit die to the plated die attach pad on the first side of the premolded lead frame assembly;
wirebonding the integrated circuit die to the plurality of conductive lead structures on the first side of the premolded lead frame assembly;
forming a second molded structure over the integrated circuit die and plurality of conductive lead structures; and
singulating the lead frame assembly, the singulating including severing the first molded structure, the second molded structure and the plurality of conductive lead structures along the parting line resulting in an integrated circuit chip package having at least one conductive lead with a side portion and a plated recessed portion.

2. The method of claim 1, wherein providing the premolded lead frame assembly includes:
providing the array of lead frames; and
forming the first molded structure at least partially between adjacent conductive lead structures along a parting line.

3. The method of claim 1, wherein forming the trench includes:
applying an etch mask, patterning the etch mask to expose at least a portion of the at least one of the plurality of conductive lead structures along the parting line; and
etching the exposed portion along the parting line.

4. The method of claim 1, wherein the trench extends entirely across a width of the at least one conductive lead structure along the parting line.

5. The method of claim 1, wherein the trench includes an arcuate profile.

6. The method of claim 1, wherein depositing the plating layer includes plating with a tin-based material.

7. The method of claim 1, wherein the singulating includes exposing the side portion of the at least one conductive lead adjacent the plated recessed portion of the at least one conductive lead.

8. The method of claim 7, wherein the integrated circuit chip package is a quad-flat-no-leads (QFN) package having a plurality of conductive leads on four sides thereof, each of the conductive leads having a respective side portion and a plated recessed portion.

9. The method of claim 1, wherein the depositing the plating layer further includes plating the die attach pads and the plurality of conductive lead structures on both the first and second sides of the premolded lead frame assembly.

10. An integrated circuit chip package comprising:
a premolded lead frame having a die attach pad, a plurality of conductive leads spaced apart from the die attach pad and each other, and a first molded structure interposed between the die attach pad and the plurality of conductive leads;
an integrated circuit die coupled to the plated die attach pad and electrically coupled to the plurality of conductive leads; and
a second molded structure encapsulating the integrated circuit die and at least a portion of the premolded lead frame;
wherein the integrated circuit chip package has a top surface, a bottom surface and a plurality of side surfaces extending between the top surface and the bottom surface, at least one of the plurality of conductive leads being exposed to at least the bottom surface and one of the plurality of side surfaces.

11. The integrated circuit chip package of claim 10, wherein at least one of the plurality of conductive leads includes a plated recessed portion extending between a side surface and the bottom surface.

12. The integrated circuit chip package of claim 10, wherein at least one of the plurality of conductive leads is comprised of copper, and the recessed portion includes a plating layer.

13. The integrated circuit package of claim 10, wherein at least one of the side surfaces of the integrated circuit package includes a portion of the first molded structure and portion of the second molded structure.

14. A method for making a lead frame, comprising:
providing an array of lead frames, each lead frame including a die attach pad and a plurality of conductive lead structures spaced apart from the die attach pad;
forming a first molded structure at least partially between adjacent conductive lead structures along a parting line;
etching a trench in at least one of the plurality of conductive lead structures along the parting line; and
depositing a plating layer over at least the trench.

15. The method of claim 14, wherein etching the trench includes:
applying an etch mask, patterning the etch mask to expose at least a portion of the at least one of the plurality of conductive lead structures along the parting line; and
etching the exposed portion along the parting line.

16. The method of claim 14, wherein the trench extends entirely across a width of the at least one conductive lead structure along the parting line.

17. The method of claim 16, wherein the trench includes an arcuate profile.

18. The method of claim 16, wherein depositing the plating layer includes plating with a tin-based material.

19. The method of claim 14, wherein the trench includes an arcuate profile.

20. The method of claim 14, wherein depositing the plating layer includes plating with a tin-based material.
